(19) United States
(12) Patent Application Publication
(10) Pub. No.: US 2007/0120464 A1
(43) Pub. Date: May 31, 2007

(54) DISPLAY

(76) Inventors: Satoshi Okutani, Ishikawa-gun (JP); Tsuyoshi Uemura, Kanazawa-shi (JP); Hirofumi Kubota, Kanazawa-shi (JP)

Correspondence Address: OBLON, SPIVAK, MCCLELLAND, MAIER & NEUSTADT, P.C., 1940 DUKE STREET, ALEXANDRIA, VA, 22314, US

(21) Appl. No.: 11/670,223

(22) Filed: Feb. 1, 2007

Related U.S. Application Data
(63) Continuation of application No. PCT/JP05/18223, filed on Sep. 26, 2005.

(30) Foreign Application Priority Data
Sep. 28, 2004 (JP) 2004-282679
Jan. 7, 2005 (JP) 2005-002898

(51) Int. Cl. H05B 33/00; H01L 51/50

(52) U.S. Cl. 313/501; 313/506; 313/512

(57) ABSTRACT

A display includes an insulating substrate, a sealing member facing the insulating substrate, pixels interposed between the insulating substrate and the sealing member and each including a microcavity structure, wherein the microcavity structure includes a reflecting layer, a half mirror layer facing the reflecting layer, and a light source interposed between the reflecting layer and the half mirror layer, and a diffusion layer facing the half mirror layer.

### CROSS REFERENCE TO RELATED APPLICATIONS

This is a Continuation Application of PCT Application No. PCT/JP2005/018223, filed Sep. 26, 2005, which was published under PCT Article 21(2) in English.

This application is based upon and claims the benefit of priority from prior Japanese Patent Applications No. 2004-282679, filed Sep. 28, 2004; and No. 2005-002898, filed Jan. 7, 2005, the entire contents of both of which are incorporated herein by reference.

### BACKGROUND OF THE INVENTION

1. Field of the Invention

The present invention relates to a display.

2. Description of the Related Art

Since organic EL displays are of self-emission type, they have a wide viewing angle and a high repose speed. In addition, they do not require a backlight, and therefore, low-profile and lightweight are possible. For these reasons, the organic EL displays are attracting attention as a display which substitutes the liquid crystal display.

An organic EL element, which is the main part of the organic EL displays, includes a light-transmitting front electrode, a light-reflecting or light-transmitting back electrode facing the front electrode, and an organic layer interposed between the electrodes and containing a light-emitting layer. The organic EL element is a charge-injection type light-emitting element which emits light when an electric current flows through the organic layer. The light emitted by the organic EL element travels as natural light with no directivity to the outside of the display through a glass substrate, for example.

The organic EL display includes a multilayer film formed on a substrate. The light emitted by the light-emitting layer causes multiple-beam interference in the multilayer film. Thus, luminous efficiency of the display and color purity of the light emitted by the display depends on a structure of the multilayer film.

Jpn. Pat. Appln. KOKAI Publication No. 11-288786 discloses an organic EL element employing an optical resonator, i.e., a micro-cavity structure. In this organic EL element, an organic layer including a light-emitting layer is sandwiched between interfaces, each of which has a high reflectance. In the micro-cavity structure, of the light beams emitted by the light-emitting layer, light having a resonant wavelength is enhanced, and light having any other wavelength is attenuated. Therefore, when the micro-cavity structure is employed for the organic EL element of the organic EL display, the luminous efficiency of the display and the color purity of the light emitted by the display can be significantly improved.

However, the inventors have found in the course of achieving the present invention that, in the case where the micro-cavity structure is employed for a display, the following problem can occur. That is, the display employing the micro-cavity structure emits light having high directivity. Thus, the brightness of a display image significantly changes in response to an observation angle. In addition, an optical length of the micro-cavity structure concerning the light traveling in an oblique direction is different from an optical length of the micro-cavity structure concerning the light traveling in the direction of the normal line to the micro-cavity structure. Therefore, when the display employs the micro-cavity structure, chromaticity of a display image changes in response to the observation angle. That is, when the micro-cavity structure is employed for the display, there is a possibility that a display quality is significantly lowered.

### BRIEF SUMMARY OF THE INVENTION

An object of the present invention to improve a display quality of a display employing a micro-cavity structure.

According to an aspect of the present invention, there is provided a display comprising an insulating substrate, a sealing member facing the insulating substrate, pixels interposed between the insulating substrate and the sealing member and each comprising a microcavity structure, wherein the microcavity structure comprises a reflecting layer, a half mirror layer facing the reflecting layer, and a light source interposed between the reflecting layer and the half mirror layer, and a diffusion layer facing the half mirror layer.

### BRIEF DESCRIPTION OF THE SEVERAL VIEWS OF THE DRAWING

FIG. 1 is a sectional view schematically showing a display according to an embodiment of the present invention;

FIG. 2 is a partial cross section of the display shown in FIG. 1;

FIG. 3 is a cross section schematically showing an example of a structure which can be employed for the display of FIGS. 2 and 3;

FIGS. 4 to 7 are sectional views each schematically showing an example of a diffusion layer which can be used for the display of FIGS. 1 and 2;

FIG. 8 is a graph showing an example of emission spectra of a display which omits a diffusion layer from the structure of FIGS. 1 and 2;

FIG. 9 is a graph showing an example of emission spectra of the display shown in FIGS. 1 and 2;

FIG. 10 is a graph showing an example of a relationship between an observation angle and display luminance;

FIG. 11 is a sectional view schematically showing a display according to a modified example;

FIGS. 12 and 13 are sectional views each schematically showing another example of a structure which can be employed for the display of FIGS. 1 and 2;

FIG. 14 is a sectional view schematically showing a display according to another modified example;

FIG. 15 is a sectional view schematically showing an example of a structure which can be employed for the display of FIG. 14;

FIG. 16 is a sectional view schematically showing an example of a structure which can be employed for a part of pixels of the display shown in FIGS. 1 and 2;

FIG. 17 is a sectional view schematically showing an example of a structure which can be employed for another part of the pixels of the display shown in FIGS. 1 and 2; and

FIG. 18 is a graph showing an example of a relationship between thickness of an optical adjustment layer and order of interference in the case where a resin layer having a refractive index of 1.5 is used as the optical adjustment layer.

### DETAILED DESCRIPTION OF THE INVENTION

An embodiment of the present invention will be described below in detail with reference to the accompanying drawings. The same reference numerals denote the same or similar constituent elements throughout the drawings, and a repetitive description thereof will be omitted.

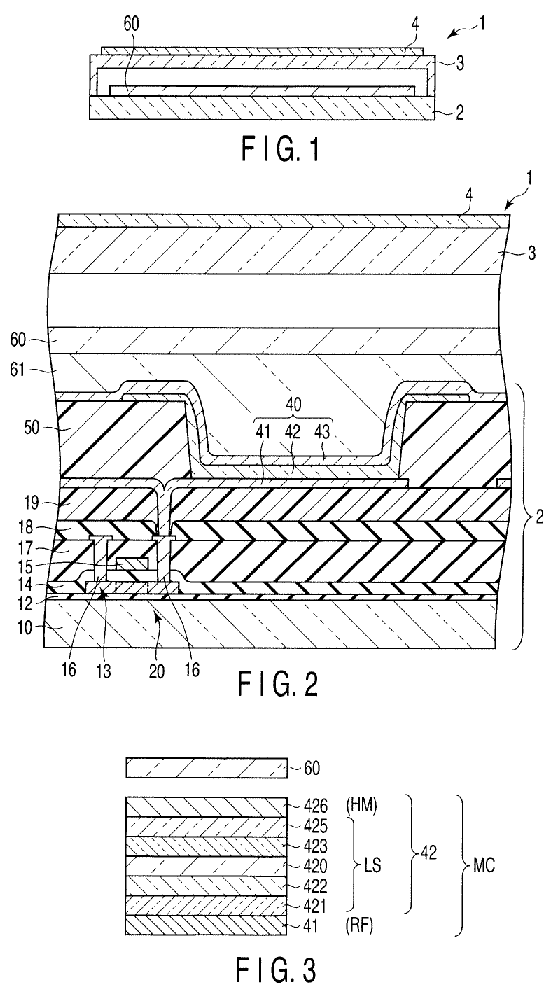

FIG. 1 is a sectional view schematically showing a display according to an embodiment of the present invention. FIG. 2 is a partial cross section of the display shown in FIG. 1. FIG. 3 is a cross section schematically showing an example of a structure which can be employed for the display of FIGS. 2 and 3. In FIGS. 1 and 2, the display is illustrated such that its display surface, that is, the front surface or the light-emitting surface, faces upwardly and the back surface faces downwardly.

The display 1 shown in FIGS. 1 and 2 is a top emission organic EL color display employing an active matrix driving method. The organic EL display 1 includes an array substrate 2 and a sealing member 3.

The sealing member 3 is a glass substrate in this example, and its surface facing the array substrate 2 has a recessed shape, for example. The array substrate 2 and the sealing substrate are joined together at peripheries thereof by means of, for example, adhesive or frit seal so as to form an enclosed space therebetween. The enclosed space is gastight and may be filled with an inert gas such as nitrogen gas or be evacuated.

A sealing technique of filling the enclosed space between the array substrate 2 and the sealing member 3 with a solid such as a resin may be utilized. Alternatively, as the sealing member 3, a film sealing technique in which an organic material layer, an inorganic material layer, or a laminate of the organic material layer and the inorganic material layer is used instead of the glass substrate may be utilized, for example.

The organic EL display 1 may further include a polarizer 4 on an outermost surface on a front side of the display. The polarizer is useful in preventing the display surface from reflecting extraneous light.

The array substrate 2 includes an insulating substrate 10 such as a glass substrate.

On the insulating substrate 10, pixels are arranged in a matrix form. Each pixel includes a pixel circuit and an organic EL element 40.

The pixel circuit includes, for example, a drive transistor (not shown) and an output control switch 20 connected in series with the organic EL element 40 between a pair of power supply terminals, and pixel switch (not shown). A gate of the drive transistor is connected via the pixel switch to a video signal line (not shown) laid correspondently with a column of the pixels. The drive transistor outputs a current, whose magnitude corresponds to a video signal supplied from the video signal line, to the organic EL element 40 via the output control switch 20. A gate of the pixel switch is connected to a scan signal line (not shown) laid correspondently with a row of the pixels. A switching operation of the pixel switch is controlled by a scan signal supplied from the scan signal line. Note that other structures can be employed for the pixels.

On the insulating substrate 10, as an undercoat layer 12, for example, an SiN_{X} layer and an SiO_{X} layer are formed in this order. A semiconductor layer 13 such as a polysilicon layer in which a channel, source and drain are formed, a gate insulator 14 which can be formed with use of, for example, TEOS (tetraethyl orthosilicate), and a gate electrode 15 made of, for example, MoW, are arranged in this order on the undercoat layer 12, and these layers form a top gate-type thin film transistor (referred to as a TFT hereinafter). In this example, the TFTs are used as the pixel switch ST, output control switch and drive transistor. Further, on the gate insulator 14, scan signal lines which can be formed in the same step as that for the gate electrode 15 are arranged.

An interlayer insulating film 17 made of, for example, SiO_{X} which is deposited by a plasma CVD method, covers the gate insulator 14 and gate electrode 15. Source and drain electrodes 16 are arranged on the interlayer insulating film 17, and they are buried in a passivation film 18 made of, for example, SiN_{X}. The source and drain electrodes 16 have, for example, a three-layer structure of Mo/Al/Mo, and electrically connected to the source and drain of the TFT via contact holes formed in the interlayer insulating film 17. Further, on the interlayer insulating film 17, video signal lines (not shown) which can be formed in the same step as that for the source and drain electrodes 16 are arranged.

A flattening layer 19 is formed on the passivation film 18. On the flattening layer 19, first electrodes 41 with light-reflection property are arranged spaced apart from one another. Each first electrode 41 is connected to a drain electrode 16 via through-holes formed in the passivation film 18 and the flattening layer 19.

The first electrode 41 is an anode in this example. As a material of the first electrode 41, for example, Al, Ag, Au and Cr can be used.

A partition insulating layer 50 is placed on the flattening layer 19. In the partition insulating layer 50, through-holes are formed at positions corresponding to the first electrodes 41. The partition insulating layer 50 is an organic insulating layer, for example, and can be formed by using a photolithography technique.

An active layer (or an organic layer) 42 including a light-emitting layer 420 is placed on each first electrode 41 which is exposed to a space in the through-hole of the partition insulating layer 50.

The light-emitting layer 420 is a thin film containing a luminescent organic compound which can generate, for example, red, green or blue light. The active layer 42 can further include a layer other than the light-emitting layer 420. For example, the active layer 42 can further include a hole transporting layer 422, a hole blocking layer 423, an electron transporting layer, an electron injection layer 425, buffer layer 426, etc. Materials of the layers other than the light-emitting layer 420 may be inorganic material or organic material.

The partition insulating layer 50 and the active layer 42 are covered with a second electrode 43 with light-transmission property. In this example, the second electrode 43 is a cathode which is continuously formed and common to all pixels. The second electrode 43 is electrically connected to an electrode wiring (not shown), the electrode wiring being formed on the layer on which the video signal lines are formed, via contact holes (not shown) formed in the passivation film 18, the flattening layer 19, and the partition insulating layer 50. Each organic EL element 40 includes the first electrode 41, active layer 42 and second electrode 43.

A diffusion layer 60 is placed on the second electrode. A variety of structures can be employed for the diffusion layer 60.

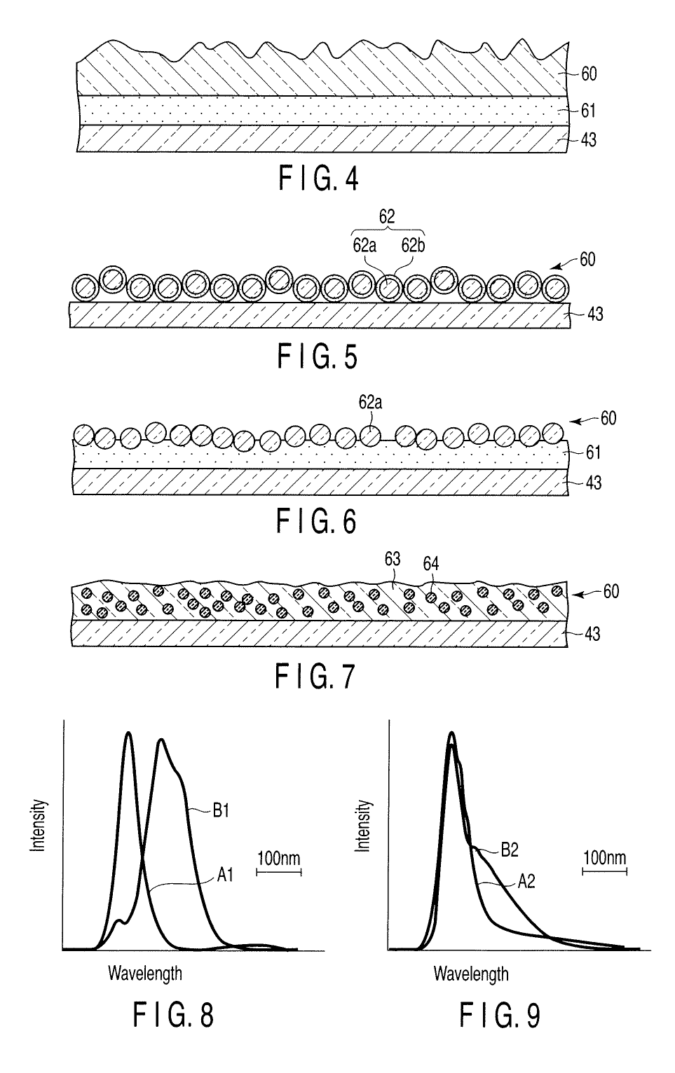

FIGS. 4 and 7 are sectional views each schematically showing an example of a diffusion layer which can be used in the display of FIGS. 1 and 2.

The diffusion layer 60 shown in FIG. 4 is a light-transmitting layer having a main surface which is provided with randomly arranged recesses and/or protrusions. The diffusion layer 60 decreases observation direction dependencies of the brightness and chromaticity of a display image. In addition, the diffusion layer 60 increases the luminous energy of the light which travels from an inside of the display 1 to its outside by its light scattering effect. That is, the diffusion layer 60 improves an outcoupling efficiency.

In the example of FIG. 2, the diffusion layer 60 shown in FIG. 4 is, for example, a resin sheet or a resin film which can be handled by itself. In this case, the diffusion layer 60 is fixed on a second electrode 43 by means of an adhesive layer 61, for example. The thickness of the adhesive layer 61 is 20 μm or more in general. Thus, even if irregularities occur on a surface of the second electrode 43, a gap is prevented from being generated between the adhesive layer 61 and the second electrode 43.

The diffusion layer 60 shown in FIG. 5 includes light-transmitting particles 62 placed on the second electrode 43. The light-transmitting particles 62 are formed by coating transparent particles 62a with an adhesive 62b. The adhesive 62b bonds the transparent particles 62a together and bonds the transparent particles 62a to the second electrode 43. The diffusion layer 60 shown in FIG. 5 can be formed by distributing the light-transmitting particles 62 over the second electrode 43 by wet or dry process. The diffusion layer 60 shown in FIG. 6 can be formed by distributing the transparent particles 62a over the adhesive layer 61 by wet or dry process. The diffusion layer 60 shown in FIGS. 5 and 6 makes it possible to improve the outcoupling efficiency by light-scattering.

The diffusion layer 60 shown in FIG. 7 is a light-scattering layer which includes a light-transmitting resin 63 and particles 64 dispersed therein. The particles 64 are different in optical property such as refractive index from the light-transmitting resin 63. The diffusion layer 60 can be formed, for example, by coating the second electrode 43 with a coating solution which contains the particles 64 and a material for the light-transmitting resin 63 and curing the obtained coating film. Note that the material for the light-transmitting resin 63 is the one which can be cured at a temperature equal to or lower than the glass transition temperature of the organic layer 42.

In the diffusion layer 60 of FIGS. 5 to 7, a material higher in refractive index than a waveguide layer such as TiO₂ or ZrO₂ may be used for the light-transmitting particles 62a and the particles 64. In this case, higher outcoupling efficiency can be achieved as compared with the case where a resin having a refractive index of about 1.5 is used.

In the display 1, the organic EL element 40 forms at least a part of a micro-cavity structure MC. The micro-cavity structure MC includes a reflection layer RF and a half mirror layer HM facing each other and a light source LS interposed between these layers. In this example, the reflection layer RF is the first electrode 41. The half mirror layer HM is, for example, a buffer layer 426 made of MgAg. The light source LS has a layered structure including a hole injection layer 421, a hole transporting layer 422, an emitting layer 420, a hole blocking layer 423, and an electron injection layer 425.

The reflection layer RF is a layer which has light-reflection property, and typically, is a metal thin film. The half mirror layer HM is a layer which has light-transmission property and light-reflection property. The half mirror layer HM has a higher transmittance as compared with the reflection layer RF. The reflection layer RF has a higher reflectance as compared with the half mirror layer HM. For example, the reflectance of the reflection layer RF is 30% or more, and the reflectance of the half mirror layer HM is 15% or more.

The micro-cavity structure MC enhances the light whose wavelength A satisfies the relationship represented by the following equation (1). On the other hand, the light whose wavelength λ satisfies the relationship represented by the following equation (2) is attenuated. In the equations, L is an optical length between the reflection layer RF and the half mirror layer HM; Φ₁ is a phase shift of light caused by being reflected on the half mirror layer HM; Φ₂ is a phase shift of light caused by being reflected on the reflection layer RF; and m is an integer.

$$\begin{matrix}\frac{2 L}{λ} + \frac{{Φ}_{1}}{2 π} + \frac{{Φ}_{2}}{2 π} = m & ( 1 ) \\ \frac{2 L}{λ} + \frac{{Φ}_{1}}{2 π} + \frac{{Φ}_{2}}{2 π} = \frac{2 m + 1}{2} & ( 2 )\end{matrix}$$

As is evident from equations (1) and (2), the luminance and color purity of an image observed in a specific direction can be improved by employing the micro-cavity structure MC. In the equations, however, the optical length L is a function of the observation angle θ. Specifically, the optical length L is proportional to 1/cos θ.

Therefore, when a minimum value L₀ of the optical length L is increased, directivity is improved. That is, a slight shift of the observation angle θ greatly influences luminance.

On the other hand, if the minimum value L0 of the optical length L is reduced, the shift of the observation angle θ less influences the luminance. However, in this case, it becomes difficult to equalize the minimum value L₀ of the optical length L between pixels having their different emitting colors. That is, there is a possibility that a display structure or its manufacturing process becomes complicated.

In this display 1, the diffusion layer 60 is placed on the front side of the micro-cavity structure MC. Therefore, as described below, it is possible to prevent brightness of a display image from significantly changing according to the observation angle or chromaticity of the display image from significantly changing according to the observation angle. That is, according to the present embodiment, a high display quality can be achieved.

FIG. 8 is a graph showing an example of emission spectra of a display which omits a diffusion layer from the structure of FIGS. 1 and 2. FIG. 9 is a graph showing an example of emission spectra of the display shown in FIGS. 1 and 2. Here, the structure of FIG. 6 has been employed for the diffusion layer 60.

In FIGS. 8 and 9, the abscissa indicates a wavelength, and the ordinate indicates emitting intensity of the display 1. Curves A1 and A2 indicate emission spectra of the display 1 in the case where a display surface has been observed in the direction of the normal line (observation angle θ=0°). Curves B1 and B2 indicate emission spectra of the display 1 in the case where the display surface has been observed in the direction crossing the direction of the normal line at an angle of 60° (observation angle θ=60°).

As shown in FIG. 8, in the display omitting the diffusion layer 60, a peak wavelength is changed by about 100 nm as the observation angle θ is changed by 60°. In contrast, in the display including the diffusion layer 60, as shown in FIG. 9, even if the observation angle θ is changed by 60°, the peak wavelength is not changed. In this manner, in the display including the micro-cavity structure MC, by placing the diffusion layer 60 on the front side of the micro-cavity structure MC, the observation direction dependency of the chromaticity can be reduced.

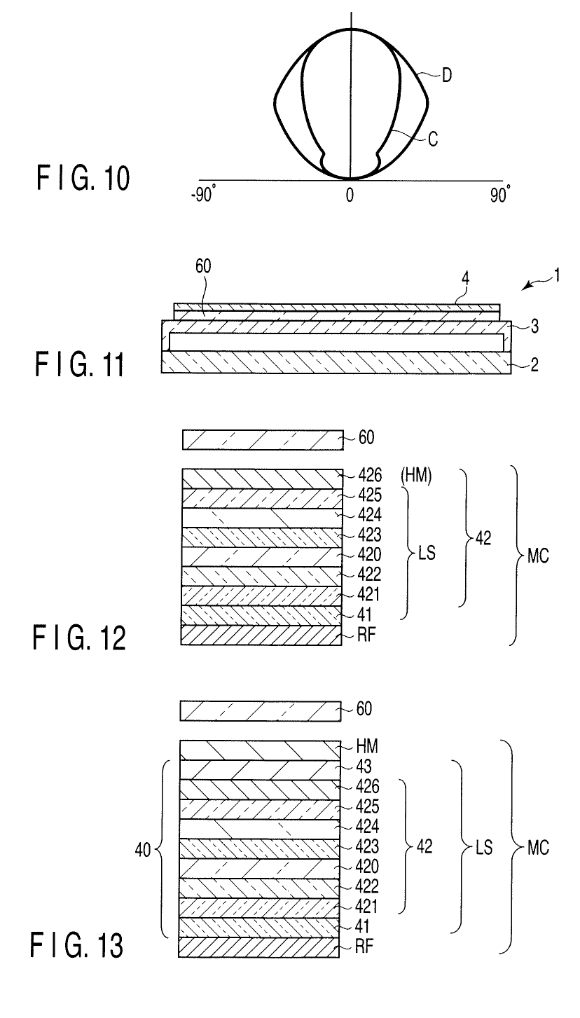

FIG. 10 is a graph showing an example of a relationship between an observation angle and display luminance. In the figure, the abscissa indicates a direction parallel to a display surface, and the ordinate indicates a direction vertical to the display surface. A curve C indicates luminance of a display omitting the diffusion layer 60 from the structure of FIGS. 1 and 2. A curve D indicates luminance of the display of FIGS. 1 and 2. A distance from an origin to a certain point on the curve C or D corresponds to luminance in the case where a display surface is seen in a direction parallel to a straight line passing through that point and the origin. An angle made by this straight line and the vertical line is defined as an observation angle θ.

As is evident from the curve C, in the display omitting the diffusion layer 60, if the observation angle θ is slightly shifted from 0°, the luminance is significantly lowered. On the other hand, in the display 1 including the diffusion layer 60, as is evident from the curve D, even if the observation angle θ is significantly shifted from 0°, the luminance is slightly lowered. That is, the display 1 including the diffusion layer 60 has smaller observation direction dependency of luminance as compared with the display omitting the diffusion layer 60.

Note that even in the case where the minimum value Lo of the optical length L is small, a slight shift of the minimum value L₀ significantly influences luminance and chromaticity. That is, in the case where the micro-cavity structure has been employed, it has been necessary to control the film thickness of each layer with high precision. In addition, if the minimum value L₀ of the optical length L is reduced, a short circuit between electrodes caused by dust adhesion is likely to occur.

In the present embodiment, in achieving the above effect, there is no need for reducing the minimum value Lo of the optical length L or there is no need for controlling the film thickness of each layer with high precision. Therefore, according to the present embodiment, a manufacturing process is facilitated and the yield can be improved.

Various modifications can be made in the display 1.

FIG. 11 is a sectional view schematically showing a display according to a modified example. The display 1 of FIG. 11 has a structure which is substantially identical to that of the display 1 of FIGS. 1 and 2 except that the diffusion layer 60 is placed between the sealing member 3 and the polarizer 4 instead of attaching the diffusion layer 60 onto the second electrode 43. Thus, a position of the diffusion layer 60 is not limited in particular as long as the layer is positioned on the front side of the micro-cavity structure MC.

Various modifications can occur in the micro-cavity structure MC of the display 1 shown in FIGS. 1 and 2.

FIGS. 12 and 13 are sectional views each schematically showing another example of a structure which can be employed for the display of FIGS. 1 and 2.

In the micro-cavity structure MC of FIG. 12, the first electrode 41 is a light transmission electrode. In addition, the reflection layer RF is placed on the back side of the first electrode 41. With exception to the above, the micro-cavity structure of FIG. 12 has a structure which is substantially identical to that of the micro-cavity structure MC of FIG. 3. Note that the micro-cavity structure MC further includes an electron transporting layer 424 between the hole blocking layer 423 and the electron injection layer 425.

In the micro-cavity structure MC of FIG. 12, an ITO (indium tin oxide) can be used as a material of the first electrode 41, for example. In addition, for example, Al, Al alloy, Ag, Ag alloy, Au, and Cu or the like can be used as a material of the reflection layer RF.

In the micro-cavity structure MC of FIG. 13, the buffer layer 426 does not serve as a half mirror layer HM, and a half mirror layer HM is placed on the second electrode 43. With exception to the above, the micro-cavity structure MC of FIG. 13 has a structure which is substantially identical to that of the micro-cavity structure MC of FIG. 12.

In the micro-cavity structure MC of FIG. 13, for example, an organic layer doped with alkaline metal and/or alkaline earth metal can be used as the buffer layer 426. In addition, a multilayer film made of dielectrics or a metal thin film can be used as the half mirror layer HM, for example.

In the case where a metal thin film is used as the half mirror layer HM, in general, a high reflectance can be obtained in a wide wavelength range. On the other hand, in the case where a multilayer film made of dielectrics is used as the half mirror layer HM, in general, a high reflectance can be obtained only in a narrow wavelength range. However, in general, in the case where a multilayer film is used, higher transmittance can be obtained.

While FIGS. 1 and 11 have shown a top emission display, the present invention can also be applied to a bottom emission display.

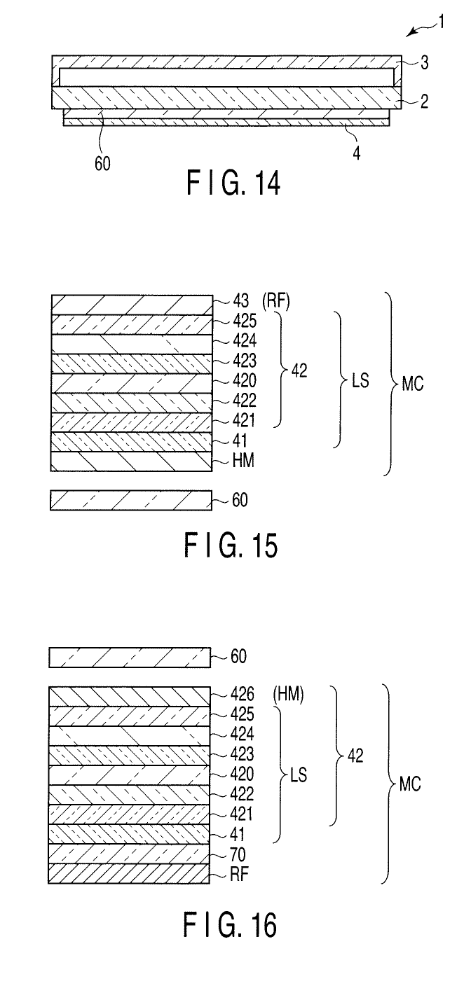

FIG. 14 is a sectional view schematically showing a display according to another modified example. FIG. 15 is a sectional view schematically showing an example of a structure which can be employed for the display of FIG. 14. In FIG. 14, the display is illustrated such that its display surface, that is, the front surface or the light-emitting surface, faces downwardly and the back surface faces upwardly.

In the display 1 of FIG. 14, unlike the display 1 of FIG. 1, the diffusion layer 60 and the polarizer 4 are sequentially arranged on an outer surface of the array substrate 2. The display 1 of FIG. 14 has a structure which is substantially identical to that of the display 1 of FIGS. 1 and 2 except that a structure of FIG. 15 has been employed in addition to the above structure.

In the structure of FIG. 15, the buffer layer 426 is omitted from the structure of FIG. 3, and an electron transporting layer 424 is further placed between the hole blocking layer 423 and the electron injection layer 425. In the structure of FIG. 15, the first electrode 41 is a light transmission electrode, the second electrode 43 is a reflection layer RF, and a half mirror layer HM is further placed on a front side of the first electrode 41.

Al and/or MgAg can be used as a material of the second electrode 43, for example. A multilayer film made of dielectrics or metal thin film can be used as the half mirror layer HM, for example.

As has been described with reference to FIGS. 1 and 11, the display 1 may be of top emission type. Alternatively, as has been described with reference to FIG. 14, the display 1 may be of bottom emission type.

As shown in FIG. 13, the entirety of an organic EL element 40 may be sandwiched between the reflection layer RF and the half mirror layer HM. That is, the organic EL element 40 may be a part of a micro-cavity structure MC. Alternatively, the organic EL element 40 itself may be the micro-cavity structure MC. Alternatively, as shown in FIGS. 2, 11, and 15, only a part of the organic EL element 40 may be sandwiched between the reflection layer RF and the half mirror layer HM. That is, a part of the organic EL element 40 may be a part of the micro-cavity structure MC.

The organic EL element 40 may emit white light. In this case, for example, a color image can be displayed by using a color filter.

The diffusion layer 60 may be placed only at positions which correspond to pixels having a specific emitting color, and may not be placed at positions which correspond to pixels having another emitting color. In this case, for example, in pixels which do not face the diffusion layer 60, an optical length L is set such that a wavelength λ meets the relationship represented by the above equation (1). By doing this, even if the wavelength does not meet the above relationship (1) in the pixels which face the diffusion layer 60, a sufficient color balance can be achieved.

The following construction may be employed for the above described display 1.

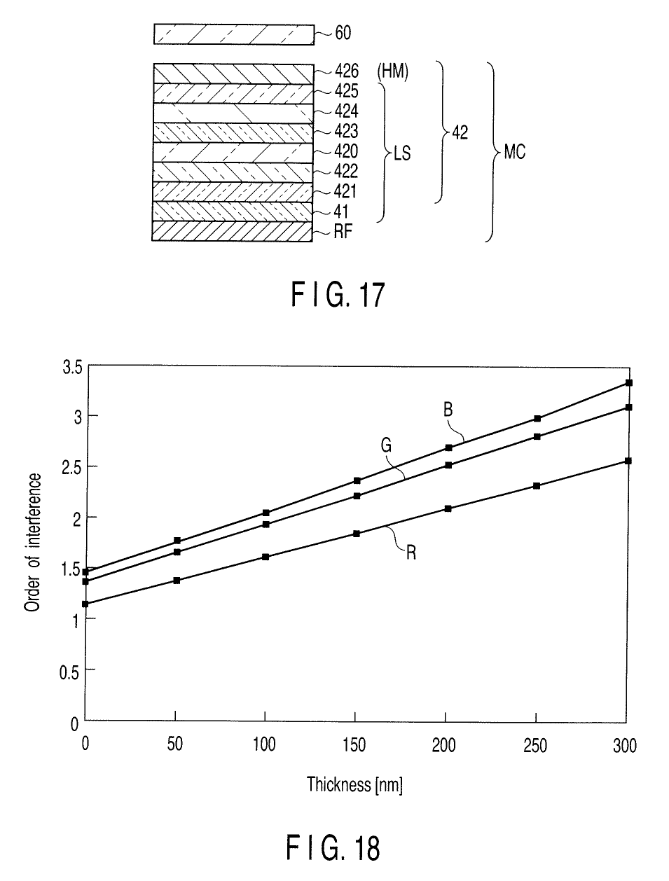

FIG. 16 is a sectional view schematically showing an example of a structure which can be employed for a part of pixels of the display shown in FIGS. 1 and 2. FIG. 17 is a sectional view schematically showing an example of a structure which can be employed for another part of the pixels of the display shown in FIGS. 1 and 2.

A structure of FIG. 16 is similar to that of FIG. 12 except that an optical adjustment layer 70 is further included between the reflection layer RF and the first electrode 41. A structure of FIG. 17 is similar to that of FIG. 12.

As is evident from the equations (1) and (2) above, the luminance in the case where a screen has been observed in the direction of the normal line depends on the wavelength λ and the optical length L. Thus, in general, in order to obtain the effect of the micro-cavity structure on improving light emission efficiency and color purity in all the pixels differing in emitting color from each other, the optical length L should be appropriately set for each emitting color.

However, in general, a layered structure of the organic EL element 40 is determined in consideration of electron-hole injection balance, degradation of luminance, etc. Thus, it may be difficult to achieve an optimal optical length L.

In such a case, for example, the structure of FIG. 16 may be employed for pixels having a certain emitting color, and the structure of FIG. 17 is employed for pixels having another emitting color. The pixel employing the structure of FIG. 16 includes the optical adjustment layer 70, and thus, is different in the optical length L from the pixel employing the structure of FIG. 17. In the pixel employing the structure of FIG. 16, the optical length L can be optimized depending on the optical characteristics and thickness of the optical adjustment layer 70. Moreover, the optical adjustment layer 70 is placed between the anode 41 and the reflection layer RF, and thus, does not influence the electron-hole injection balance, degradation of luminance, etc.

Therefore, when the structure of FIG. 16 is employed for pixels having a certain emitting color and the structure of FIG. 17 is employed for pixels having another emitting color, the luminance or the like in the case where a screen has been observed in the direction of the normal line can be optimized without influencing the electron-hole injection balance, degradation of luminance, etc. That is, it becomes possible to achieve more excellent display quality.

FIG. 18 is a graph showing an example of a relationship between thickness of an optical adjustment layer and order of interference in the case where a resin layer having a refractive index of 1.5 is used as the optical adjustment layer. In the figure, the abscissa indicates the thickness of an optical adjustment layer 70 and the ordinate indicates an order of interference which is caused by the light traveling in the micro-cavity structure MC in the direction normal to a film surface. In addition, in the figure, reference symbols B, G, and R indicate data obtained by carrying out simulation for pixels whose emitting colors are blue (λ=480 nm), green (λ=530 nm), and red (λ=630 nm), respectively. In the simulation, it is presumed that the organic EL elements 40 whose emitting colors are blue, green, and red have the same structure except that a material for the emitting layer 420 is different.

According to the data shown in FIG. 18, in the pixels whose emitting colors are blue and green, when the thickness of the optical adjustment layer 70 is set to, for example, about 100 nm, an order of interference is obtained as a value close to an integer (about 2). On the other hand, in the pixels whose emitting color is red, when the optical adjustment layer 70 is not placed, an order of interference is obtained as a value close to an integer (about 1). That is, when an optical adjustment layer 70 having thickness of about 100 nm is placed only in the pixels whose emitting colors are blue and green, high front brightness can be obtained in respective pixels of different emission colors.

In this embodiment, the optical adjustment layer 70 is placed between the anode 41 and the reflection layer RF only in the pixels of specific emission color. The above described effect can also be obtained when another structure is employed. For example, it is possible to employ a structure in which the optical adjustment layer 70 is placed between the anode 41 and the reflection layer RF in all the pixels and the optical thickness of the optical adjustment layer 70 is different between the pixels whose emitting colors are different from each other. For example, in an example shown in FIG. 18, the optical adjustment layer 70 having thickness of about 100 nm may be placed in the pixels whose emitting colors are blue and green, and the optical adjustment layer 70 having thickness of 180 nm may be placed in the pixels whose emitting color is red.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A display comprising:
an insulating substrate;
a sealing member facing the insulating substrate;
pixels interposed between the insulating substrate and the sealing member and each comprising a microcavity structure, wherein the microcavity structure comprises a reflecting layer, a half mirror layer facing the reflecting layer, and a light source interposed between the reflecting layer and the half mirror layer; and
a diffusion layer facing the half mirror layer.

2. The display according to claim 1, wherein the display is a color display.

3. The display according to claim 1, wherein the display is an organic EL display.

4. The display according to claim 3, wherein the light source includes an emitting layer of an organic EL element.

5. The display according to claim 4, wherein the reflecting layer is a back electrode of the organic EL element.

6. The display according to claim 4, wherein the half mirror layer is a front electrode of the organic EL element.

7. The display according to claim 4, wherein the organic EL element is interposed between the reflecting layer and the half mirror layer.

8. The display according to claim 1, wherein the half mirror layer is a metal layer.

9. The display according to claim 1, wherein the half mirror layer is a multilayer film made of dielectrics.

10. The display according to claim 4, wherein the pixels includes first and second pixels different in emitting color from each other,
wherein each of the first and second pixels further comprises a back electrode of the organic EL element interposed between the emitting layer and the reflecting layer, and
wherein, of the first and second pixels, only the first pixel further comprises an optically adjusting layer with light transmitting property interposed between the reflecting layer and the back electrode.

11. The display according to claim 4, wherein the pixels includes first and second pixels different in emitting color from each other,
wherein each of the first and second pixels further comprises a back electrode of the organic EL element interposed between the emitting layer and the reflecting layer, and an optically adjusting layer with light transmitting property interposed between the reflecting layer and the back electrode, and
wherein the first and second pixels are different in optical thickness of the optically adjusting layer from each other.
